(19) United States
(12) Patent Application Publication
(10) Pub. No.: US 2012/0069686 A1
(43) Pub. Date: Mar. 22, 2012

(54) LATCH TIMING ADJUSTMENT DEVICE AND MEMORY ACCESS SYSTEM USING THE SAME

(75) Inventor: Hisataka NAKABAYASHI, Hyogo (JP)

(73) Assignee: Panasonic Corporation, Osaka (JP)

(21) Appl. No.: 13/307,684

(22) Filed: Nov. 30, 2011

Related U.S. Application Data
(63) Continuation of application No. PCT/JP2010/003180, filed on May 10, 2010.

(30) Foreign Application Priority Data
Jun. 19, 2009 (JP) 2009-146750

(51) Int. Cl. G11C 7/10

(52) U.S. Cl. 365/189.05

(57) ABSTRACT

A latch timing adjustment device includes: first to third variable delay sections configured to delay a strobe signal by first to third variable delay amounts, respectively; first to third data latch sections configured to latch a data signal in response to the outputs of the first to third variable delay sections, respectively; a comparison section configured to perform comparison between the outputs of the first and second data latch sections and comparison between the outputs of the second and third data latch sections; and a delay adjustment section configured to adjust the first and third variable delay amounts based on the comparison results from the comparison section, and adjust the second variable delay amount based on the first and third variable delay amounts adjusted.

### CROSS-REFERENCE TO RELATED APPLICATION

This is a continuation of PCT International Application PCT/JP2010/003180 filed on May 10, 2010, which claims priority to Japanese Patent Application No. 2009-146750 filed on Jun. 19, 2009. The disclosures of these applications including the specifications, the drawings, and the claims are hereby incorporated by reference in their entirety.

### BACKGROUND

The present disclosure relates to a memory access system, and more particularly to the technology of adjusting data latch timing.

In recent memory systems, with the trend toward large-capacity, high-speed data processing, memory devices capable of inputting/outputting data in synchronization with a clock signal, such as synchronous dynamic random access memory (SDRAM), have been often used. In such memory devices, a data signal (DQ) is input/output in synchronization with both rising and falling edges of a data strobe signal (DQS).

Also, memory devices adopting a double data rate (DDR) scheme, where the operation of input/output circuits are sped up to increase the data transfer speed in an attempt to increase the data amount read/written at one time, have become mainstream. In the DDR scheme, input/output circuits are driven at a low voltage for power reduction. As a result, the valid duration of the data signal with respect to the strobe signal tends to be short. Also, considering fluctuations in the timing relationship between the data signal and the strobe signal caused by variations in fabrication process, temperature change, voltage change, etc., stable data input/output becomes difficult.

As one of means for solving the above problem, calibration has been performed for adjusting the timing at which the data signal is latched with the strobe signal. For example, before performing normal memory access operation, the following operation is performed. A plurality of delay amounts are set in variable delay sections, and the data signal is latched with delayed strobe signals delayed by these delay amounts. Out of the results of comparison of the latched values, a strobe signal corresponding to the mean value, for example, is considered as the optimum strobe signal in the normal memory access operation, whereby the data latch timing is adjusted (see Japanese Patent Publication No. 2004-185608, for example).

### SUMMARY

The conventional data latch adjustment device performs calibration before normal memory access operation. Therefore, when the latch timing of the data signal fluctuates during the normal memory access operation, it is necessary to halt the operation and perform the calibration again. This causes a problem of impeding speedup of the memory access operation.

According to an example latch timing adjustment device of the present disclosure, latch timing can be adjusted during normal memory access operation.

As one example, a latch timing adjustment device of the present disclosure configured to adjust latch timing of a data signal output from a memory includes: a first variable delay section configured to delay a strobe signal output from the memory by a first variable delay amount; a second variable delay section configured to delay the strobe signal by a second variable delay amount; a third variable delay section configured to delay the strobe signal by a third variable delay amount; a first data latch section configured to latch the data signal in response to an output of the first variable delay section; a second data latch section configured to latch the data signal in response to an output of the second variable delay section; a third data latch section configured to latch the data signal in response to an output of the third variable delay section; a comparison section configured to perform first comparison between an output of the first data latch section and an output of the second data latch section and second comparison between the output of the second data latch section and an output of the third data latch section; and a delay adjustment section configured to adjust the first variable delay amount if the result of the first comparison indicates a non-match, adjust the third variable delay amount if the result of the second comparison indicates a non-match, and adjust the second variable delay amount based on the first and third variable delay amounts adjusted.

With the above configuration, the data signal output from the memory is latched with delayed strobe signals delayed by three different variable delay amounts. The first variable delay amount is adjusted if the result of the first comparison indicates a non-match, the third variable delay amount is adjusted if the result of the second comparison indicates a non-match, and further the second variable delay amount is adjusted based on these adjustments. With this feedback control of the variable delay amounts, the outputs of the data latch sections come to match with one another. Thus, the timing at which the data signal is latched can be adjusted during normal memory access operation.

Specifically, the delay adjustment section may increase the first variable delay amount if the result of the first comparison indicates a non-match, and decrease the third variable delay amount if the result of the second comparison indicates a non-match. With this configuration, even if the valid duration of the data signal varies, the first variable delay amount can be increased to correspond to the start position of the valid duration, and also the third variable delay amount can be decreased to correspond to the end position of the valid duration, thereby permitting to respond to any variation in valid duration.

Also, specifically, the delay adjustment section may use a mean value between the first and third variable delay amounts as the second variable delay amount. With this configuration, even when the valid duration of the data signal varies, latching can be made precisely within the valid duration.

The delay adjustment section may be implemented on a CPU, the latch timing adjustment device may further include a holder configured to hold the first to third variable delay amounts, and the first to third variable delay sections may delay the strobe signal by the first to third variable delay amounts held in the holder. With this configuration, since the circuit configuration of the delay adjustment section can be omitted, the circuit scale of the latch timing adjustment device can be reduced.

Preferably, the first to third variable delay sections are connected in series. The first to third data latch sections may latch the data signal at timing of both rising and falling edges of the outputs of the first to third variable delay sections.

Alternatively, a memory access system of the present disclosure includes: the latch timing adjustment device described above; and a power supply circuit configured to control a power supply voltage supplied to the latch timing adjustment device and the memory based on a difference between the first variable delay amount and the third variable delay amount in the latch timing adjustment device. Preferably, the memory access system further includes a temperature detection circuit configured to detect a temperature of the memory, wherein the power supply circuit controls the power supply voltage based on a result of detection by the temperature detection circuit.

With the above configuration, the latch timing of the data signal can be adjusted irrespective of occurrence of a voltage change and a temperature change. This can improve the performance of the memory access.

### BRIEF DESCRIPTION OF THE DRAWINGS

FIG. 1 is a block diagram of a latch timing adjustment device of the first embodiment.

FIG. 2 is a flowchart of the operation of the latch timing adjustment device of FIG. 1.

FIG. 3 is a block diagram of a latch timing adjustment device of a variation of the first embodiment.

FIG. 4 is a block diagram of a memory access system of the second embodiment.

FIG. 5 is a flowchart of the operation of the memory access system of FIG. 4.

FIG. 6 is a block diagram of a memory access system of a variation of the second embodiment.

FIG. 7 is a flowchart of the operation of the memory access system of FIG. 6.

### DETAILED DESCRIPTION

Embodiments of the present disclosure will be described hereinafter with reference to the accompanying drawings.

### First Embodiment

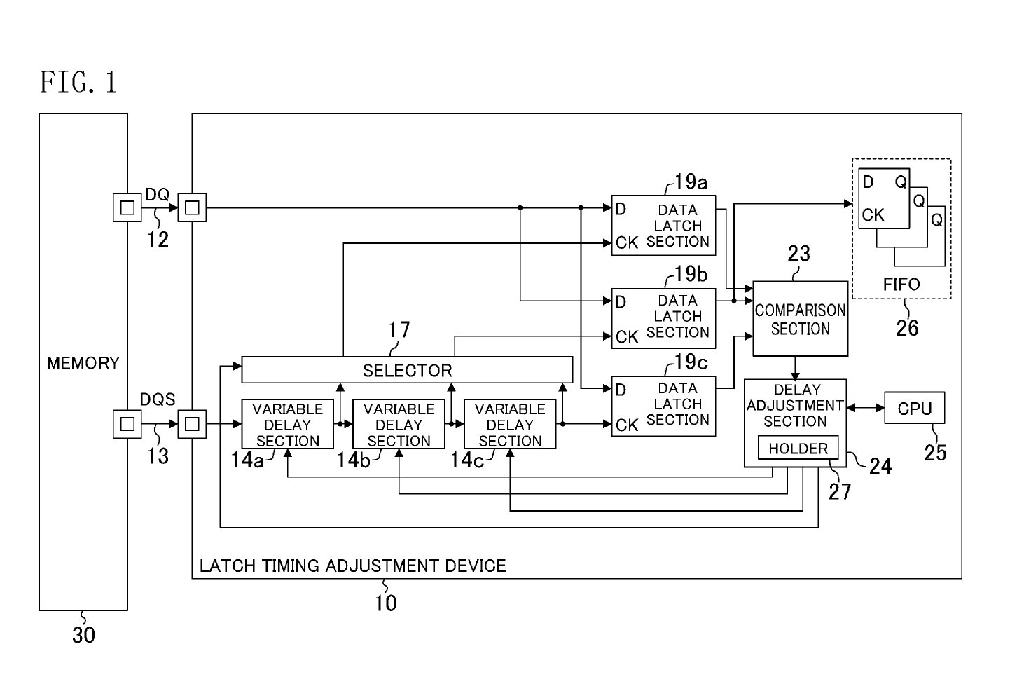

FIG. 1 is a block diagram of a latch timing adjustment device 10 of the first embodiment. The latch timing adjustment device 10, connected to a memory 30 via a data signal line 12 and a strobe signal line 13, adjusts the latch timing of a data signal DQ output from the memory 30.

A variable delay section 14a delays a strobe signal DQS output from the memory 30 by a set variable delay amount. A variable delay section 14b delays the output of the variable delay section 14a by a set variable delay amount. A variable delay section 14c delays the output of the variable delay section 14b by a set variable delay amount. The variable delay sections 14a, 14b, and 14c can be comprised of a plurality of delay cells, for example.

A data latch section 19a latches the data signal DQ at timing of both rising and falling edges of the output of the variable delay section 14a. A data latch section 19b latches the data signal DQ at timing of both rising and falling edges of the output of the variable delay section 14b, and a data latch section 19c latches the data signal DQ at timing of both rising and falling edges of the output of the variable delay section 14c.

Note that, at the time of initial setting processing of the latch timing adjustment device 10, the data latch section 19b latches the data signal DQ with one of the outputs of the variable delay sections 14a, 14b, and 14c selected by a selector 17.

A FIFO circuit section 26 sequentially stores the data signal DQ latched by the data latch section 19b. The data signal DQ stored in the FIFO circuit section 26 is read and processed by a CPU 25.

A comparison section 23 compares the outputs of the data latch sections 19a and 19b with each other and also compares the outputs of the data latch sections 19b and 19c with each other.

A delay adjustment section 24 adjusts the variable delay amounts set in the variable delay sections 14a, 14b, and 14c when the result of comparison between the outputs of the data latch sections 19a and 19b and the result of comparison between the outputs of the data latch sections 19b and 19c indicate a non-match. More specifically, when the outputs of the data latch sections 19a and 19b do not match with each other, the variable delay amount set in the variable delay section 14a is increased. Contrarily, when the outputs of the data latch sections 19b and 19c do not match with each other, the variable delay amount set in the variable delay section 14c is decreased. The mean value between the variable delay amounts set in the variable delay sections 14a and 14c is used as the variable delay amount set in the variable delay section 14b. A holder 27 holds the three variable delay amounts.

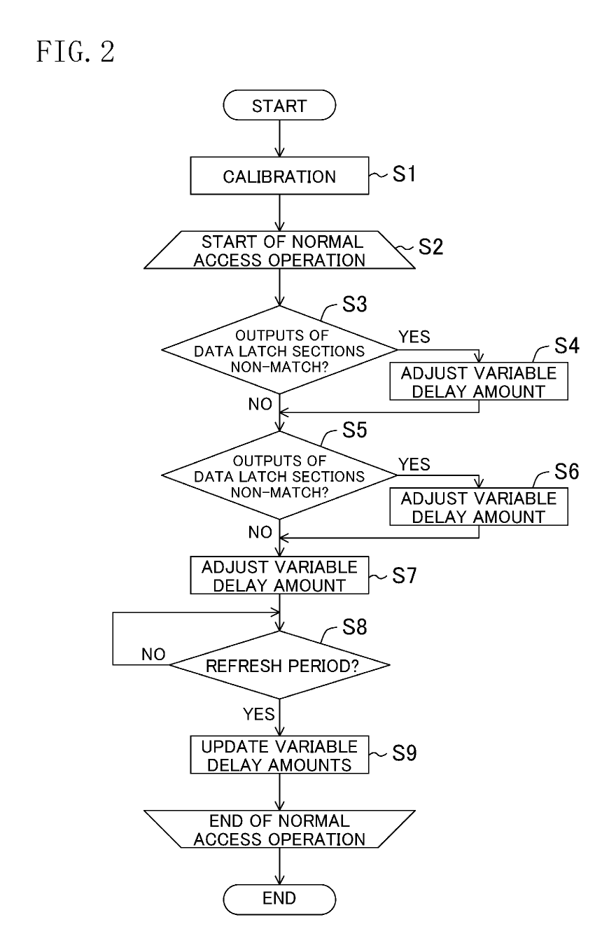

Next, the operation of the latch timing adjustment device 10 of this embodiment will be described with reference to FIGS. 1 and 2. FIG. 2 is a flowchart of the operation of the latch timing adjustment device 10. First, before start of normal memory access operation, e.g., immediately after power-on, the CPU 25 performs calibration as initialization processing, to determine the variable delay amounts to be set in the variable delay sections 14a, 14b, and 14c (step S1).

More specifically, the CPU 25 assigns in advance initial variable delay amounts to the variable delay sections 14a, 14b, and 14c. The selector 17 selects the output of the variable delay section 14a under instructions from the CPU 25. The variable delay section 14a delays the strobe signal DQS by the set variable delay amount. The data latch section 19b, receiving the output of the variable delay section 14a via the selector 17, latches the data signal DQ.

Likewise, under instructions from the CPU 25, the selector 17 sequentially selects the outputs of the variable delay sections 14b and 14c. The data latch section 19b, receiving the outputs of the variable delay sections 14b and 14c via the selector 17, latches the data signal DQ sequentially.

Thereafter, the CPU 25 measures the valid duration of the data signal DQ from the expected values of the three latched data signals DQ in the data latch section 19b. The CPU 25 then determines the variable delay amount to be set in the variable delay section 14a so that an edge of the output of the variable delay section 14a coincides with the start position of the valid duration, and also determines the variable delay amount to be set in the variable delay section 14c so that an edge of the output of the variable delay section 14c coincides with the end position of the valid duration. Moreover, the CPU 25 uses the mean value between the variable delay amounts set in the variable delay sections 14a and 14c as the variable delay amount to be set in the variable delay section 14b. The holder 27 holds the three variable delay amounts.

The latch timing adjustment device 10 then performs the normal memory access operation (step S2).

Next, the latch timing adjustment during the normal memory access operation will be described. The data latch sections 19a, 19b, and 19c respectively latch the data signal DQ with the outputs of the variable delay sections 14a, 14b, and 14c. The comparison section 23 compares the outputs of the data latch sections 19a and 19b with each other (step S3). If the comparison result indicates a non-match (YES in step S3), the delay adjustment section 24 increases the variable delay amount set in the variable delay section 14a by an amount of one delay cell, for example (step S4).

The comparison section 23 further compares the outputs of the data latch sections 19b and 19c with each other (step S5). If the comparison result indicates a non-match (YES in step S5), the delay adjustment section 24 decreases the variable delay amount set in the variable delay section 14c by an amount of one delay cell, for example (step S6).

When having adjusted the two variable delay amounts, the delay adjustment section 24 calculates the mean value between the variable delay values set in the variable delay sections 14a and 14c as the variable delay amount to be set in the variable delay section 14b (step S7).

Thereafter, the delay adjustment section 24 judges whether the memory 30 is performing refresh operation that does not affect the normal memory access operation (step S8). If judging that refresh operation is being performed (YES in step S8), the delay adjustment section 24 stores the three adjusted variable delay amounts in the holder 27 and also updates the variable delay amounts in the variable delay sections 14a, 14b, and 14c with the adjusted ones (step S9). The series of the steps S2 through S9 are repeated during the normal memory access operation, and the latch timing adjustment is terminated once the normal memory access operation is terminated.

The variable delay sections 14a, 14b, and 14c may be connected in parallel. The step S5 may be performed prior to the step S3, and the step S6 may be performed prior to the step S4. Otherwise, the steps S3 and S5 may be performed simultaneously, and the steps S4 and S6 may be performed simultaneously.

As described above, in this embodiment, even during normal memory access operation, the timing at which the data signal DQ is latched in its valid duration can be adjusted. Thus, the data signal DQ can be latched correctly.

### Variation of First Embodiment

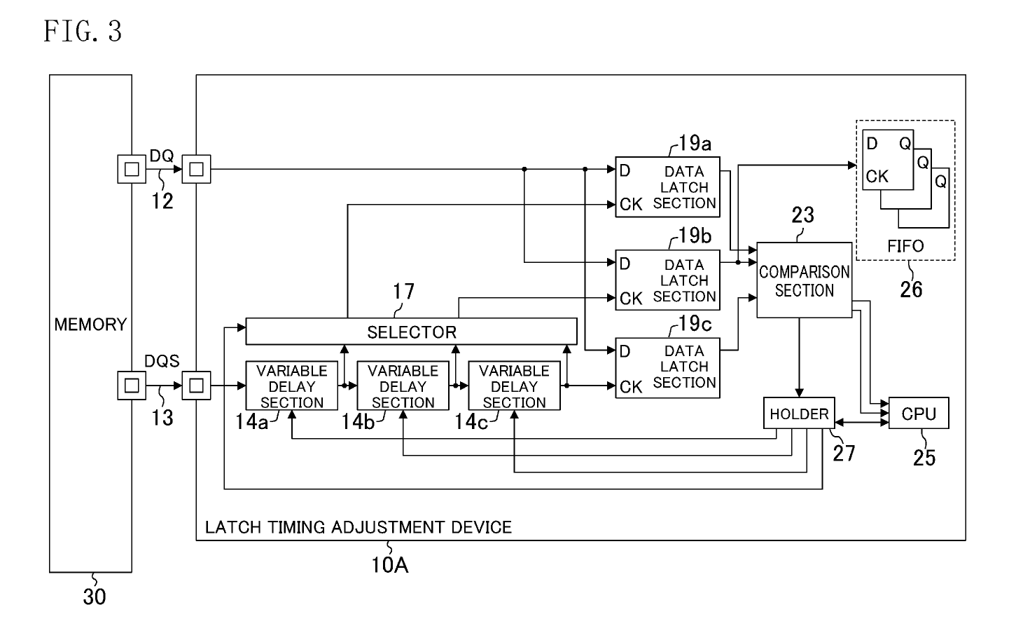

FIG. 3 is a block diagram of a latch timing adjustment device 10A of a variation of the first embodiment. In the latch timing adjustment device 10A, the comparison section 23 is connected to the CPU 25, to allow the CPU 25 to execute the processing that is executed by the delay adjustment section 24 in the latch timing adjustment device 10 of the first embodiment.

The CPU 25 adjusts the three variable delay amounts based on the comparison results from the comparison section 23 during normal memory access operation. The holder 27 holds the three adjusted variable delay amounts. The variable delay sections 14a, 14b, and 14c delay the strobe signal DQS by the corresponding variable delay amounts held in the holder 27.

Thus, in this variation, since the circuit configuration of the delay adjustment section 24 can be omitted, the circuit scale of the latch timing adjustment device 10A can be reduced.

### Second Embodiment

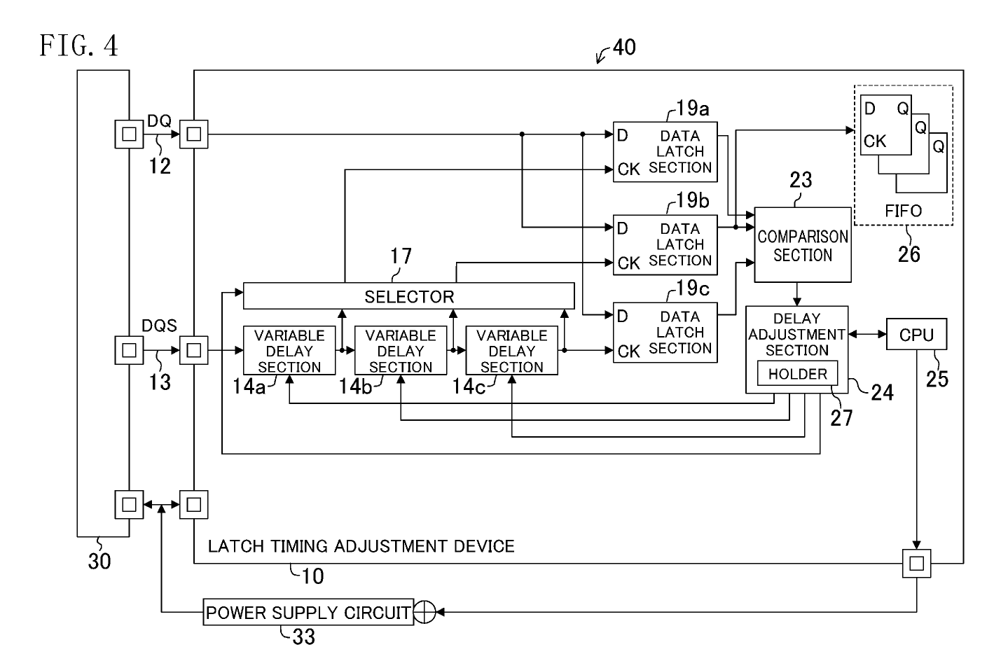

FIG. 4 is a block diagram of a memory access system 40 of the second embodiment. Note that, in this embodiment, only the point different from the first embodiment will be described.

A power supply circuit 33 supplies a voltage specified by the CPU 25 to the latch timing adjustment device 10 and the memory 30.

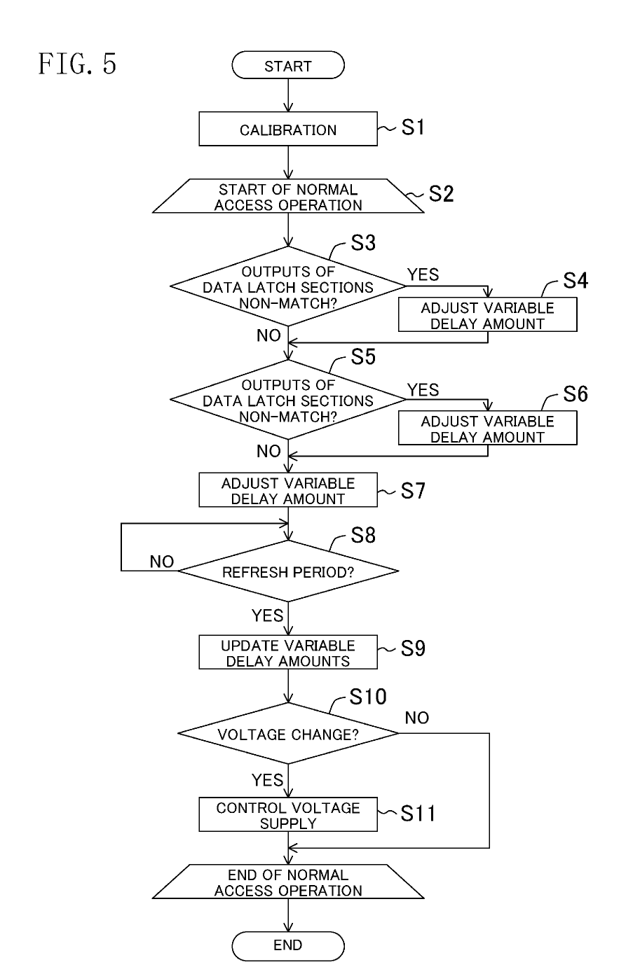

The operation of the memory access system 40 of this embodiment will be described with reference to FIGS. 4 and 5. FIG. 5 is a flowchart of the operation of the memory access system 40.

During normal memory access operation, the CPU 25 determines whether there is a change in power supply voltage in the latch timing adjustment device 10 and the memory 30 (step S10). If there is a change (YES in step S10), the power supply circuit 33 changes the power supply voltage supplied to the latch timing adjustment device 10 and the memory 30 (step S11).

More specifically, when having detected a drop in power supply voltage and at this time found that the difference between the variable delay amounts in the variable delay sections 14a and 14c is smaller than a predetermined value, the CPU 25 outputs a voltage signal for increasing the power supply voltage. Having received the voltage signal, the power supply circuit 33 increases the power supply voltage supplied to the latch timing adjustment device 10 and the memory 30.

Contrarily, when having detected a rise in power supply voltage and at this time found that the difference between the variable delay amounts in the variable delay sections 14a and 14c is larger than a predetermined value, the CPU 25 outputs a voltage signal for decreasing the power supply voltage. Having received the voltage signal, the power supply circuit 33 decreases the power supply voltage supplied to the latch timing adjustment device 10 and the memory 30.

As described above, in this embodiment, even if the valid duration of the data signal DQ varies due to a change in power supply voltage, the latch timing can be adjusted in accordance with the variation.

### Variation of Second Embodiment

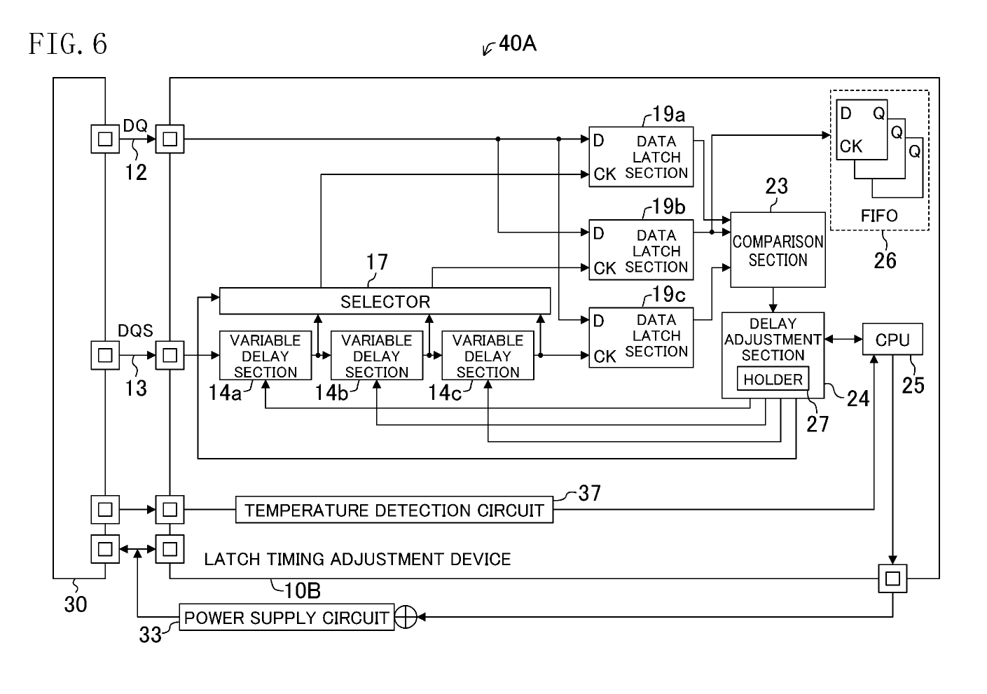

FIG. 6 is a block diagram of a memory access system 40A of a variation of the second embodiment. A latch timing adjustment device 10B includes a temperature detection circuit 37. The temperature detection circuit 37 outputs a temperature detection signal in response to a signal indicating the temperature received from the memory 30.

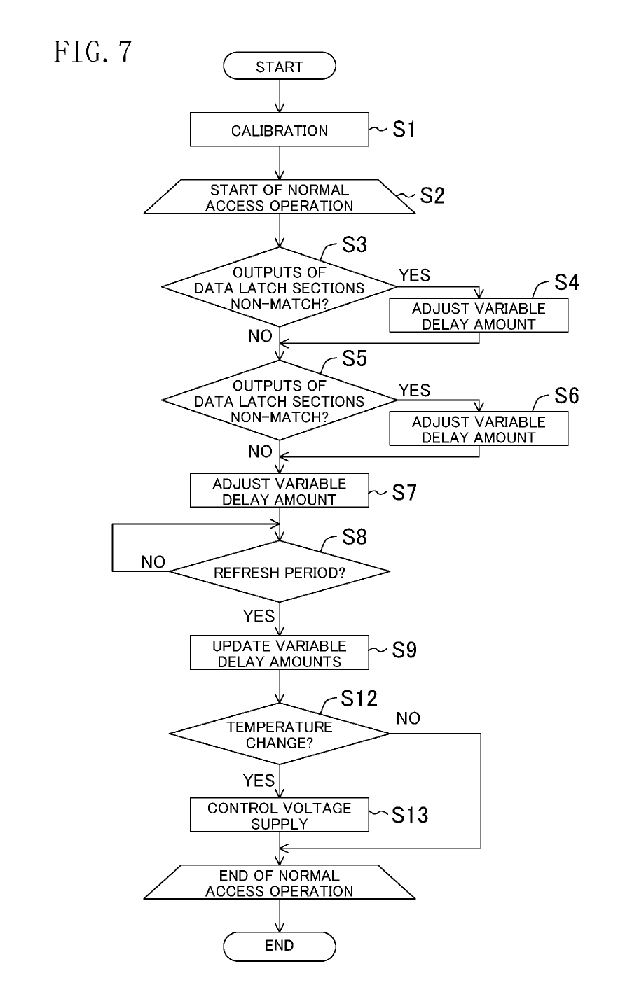

The operation of the memory access system 40A of this embodiment will be described with reference to FIGS. 6 and 7. FIG. 7 is a flowchart of the operation of the memory access system 40A. Note that, since the processing up to the step S9 is the same as that in the second embodiment, description of this processing is omitted here.

During normal memory access operation, the temperature detection circuit 37 detects whether there is a change in the temperature of the memory 30 (step S12). If there is a change (YES in step S12), the power supply circuit 33 controls the power supply voltage supplied to the latch timing adjustment device 10B and the memory 30 (step S13).

More specifically, when having detected that the temperature of the memory 30 is higher than a predetermined temperature, the temperature detection circuit 37 outputs a temperature detection signal indicating high temperature. In response to this, the CPU 25 outputs a voltage signal for decreasing the power supply voltage. Having received the voltage signal, the power supply circuit 33 decreases the power supply voltage supplied to the latch timing adjustment device 10B and the memory 30.

Contrarily, when having detected that the temperature of the memory 30 has returned to the predetermined temperature, the temperature detection circuit 37 outputs a temperature detection signal indicating normal temperature. In response to this, the CPU 25 outputs a voltage signal for restoring the power supply voltage to its original value. Having received the voltage signal, the power supply circuit 33 restores the power supply voltage supplied to the latch timing adjustment device 10B and the memory 30 to its original value.

In this variation, the power supply voltage may be controlled considering the valid duration of the data signal DQ in addition to the temperature change.

As described above, in this variation, the latch timing of the data signal DQ can be adjusted even if the temperature changes during normal memory access operation.

What is claimed is:

1. A latch timing adjustment device configured to adjust latch timing of a data signal output from a memory, the device comprising:
a first variable delay section configured to delay a strobe signal output from the memory by a first variable delay amount;
a second variable delay section configured to delay the strobe signal by a second variable delay amount;
a third variable delay section configured to delay the strobe signal by a third variable delay amount;
a first data latch section configured to latch the data signal in response to an output of the first variable delay section;
a second data latch section configured to latch the data signal in response to an output of the second variable delay section;
a third data latch section configured to latch the data signal in response to an output of the third variable delay section;
a comparison section configured to perform first comparison between an output of the first data latch section and an output of the second data latch section and second comparison between the output of the second data latch section and an output of the third data latch section; and
a delay adjustment section configured to adjust the first variable delay amount if the result of the first comparison indicates a non-match, adjust the third variable delay amount if the result of the second comparison indicates a non-match, and adjust the second variable delay amount based on the first and third variable delay amounts adjusted.

2. The latch timing adjustment device of claim 1, wherein
the delay adjustment section increases the first variable delay amount if the result of the first comparison indicates a non-match, and decreases the third variable delay amount if the result of the second comparison indicates a non-match.

3. The latch timing adjustment device of claim 1, wherein
the delay adjustment section uses a mean value between the first and third variable delay amounts as the second variable delay amount.

4. The latch timing adjustment device of claim 2, wherein
the delay adjustment section uses a mean value between the first and third variable delay amounts as the second variable delay amount.

5. The latch timing adjustment device of claim 1, wherein
the delay adjustment section is implemented on a CPU,
the latch timing adjustment device further includes a holder configured to hold the first to third variable delay amounts, and
the first to third variable delay sections delay the strobe signal by the first to third variable delay amounts held in the holder.

6. The latch timing adjustment device of claim 1, wherein
the first to third variable delay sections are connected in series.

7. The latch timing adjustment device of claim 1, wherein
the latch timing adjustment device is connected to the memory via a data signal line for transmission of the data signal and a strobe signal line for transmission of the strobe signal.

8. The latch timing adjustment device of claim 1, wherein
the first to third data latch sections latch the data signal at timing of both rising and falling edges of the outputs of the first to third variable delay sections.

9. A memory access system comprising:
the latch timing adjustment device of claim 1; and
a power supply circuit configured to control a power supply voltage supplied to the latch timing adjustment device and the memory based on a difference between the first variable delay amount and the third variable delay amount in the latch timing adjustment device.

10. The memory access system of claim 9, further comprising:
a temperature detection circuit configured to detect a temperature of the memory, wherein
the power supply circuit controls the power supply voltage based on a result of detection by the temperature detection circuit.
